(19) United States
(12) Patent Application Publication
(10) Pub. No.: US 2013/0217178 A1
(43) Pub. Date: Aug. 22, 2013

(54) METHOD AND APPARATUS FOR MANUFACTURING A THIN FILM PHOTOVOLTAIC CELL

(71) Applicant: Fuji Electric Co., Ltd., (US)

(72) Inventor: Taketo TSUJI, Chiba-city (JP)

(73) Assignee: FUJI ELECTRIC CO., LTD., Kawasaki-shi (JP)

(21) Appl. No.: 13/769,252

(22) Filed: Feb. 15, 2013

(30) Foreign Application Priority Data
Feb. 17, 2012 (JP) 2012-032395

(51) Int. Cl. G06F 17/50; H01L 31/18

(52) U.S. Cl. CPC G06F 17/5045; H01L 31/18
USPC 438/98; 716/132

(57) ABSTRACT

A method for manufacturing a thin film photovoltaic cell having a first electrode layer, a photoelectric conversion layer including a plurality of photoelectric conversion cells, and a second electrode layer sequentially formed on a substrate. The method includes calculating a difference between a weighted mean wavelength of spectral sensitivity of the photoelectric conversion layer and a weighted mean wavelength of a spectrum of incident sunlight that is at a place of installation of the thin film photovoltaic cell and is in a wavelength range contributing to power generation by the thin film photovoltaic cell, and determining a structure of the photoelectric conversion cells, such that the difference is confined to a predetermined range.

### CROSS-REFERENCE TO RELATED APPLICATION

This application is based on, and claims priority to, Japanese Patent Application No. 2012-032395, filed on Feb. 17, 2012, contents of which are incorporated herein by reference.

### BACKGROUND OF THE INVENTION

1. Field of the Invention

The present invention relates to a method and apparatus for manufacturing a thin film photovoltaic cell with high power generation efficiency.

2. Description of the Related Art

Thin film photovoltaic cells, with their thin shape, light weight, low manufacturing costs, and ease of obtaining large area devices, are expected to become the mainstream of photovoltaic cells in the future. Demands for thin film photovoltaic cells are expanding to business buildings and houses where photovoltaic cells are mounted on roofs and windows, and are used for power supply.

In order to improve performance of the thin film photovoltaic cells, a multiple junction structure that includes multiple formed cells with different absorption wavelength bands is being explored.

Photoelectric conversion cells using amorphous silicon (hereinafter also referred to as an “a-Si cells”), for example, have an absorption peak around 480 nm and an absorption band in the range of 350 nm to 700 nm; and photoelectric cells using amorphous silicon-germanium (also referred to as an “a-SiGe cells”) have an absorption peak around 700 nm and an absorption band in the range of 500 nm to 900 nm. A multiple junction type thin film photovoltaic cell having an a-Si cell and an a-SiGe cell formed from the light incident side in this order, therefore, absorbs light of short wavelengths in the a-Si cell and absorbs light of long wavelengths that has passed through the a-Si cell in the a-SiGe cell. Therefore, the multiple junction type thin film photovoltaic cell as a whole absorbs light in a wide wavelength range, achieving improved power generation efficiency.

Performance evaluation has been discussed in JIS (Japanese Industrial Standards) and IEC (International Electrotechnical Committee). JIS include standards involved with photovoltaic cell modules: JIS C 8914 (Measuring methods of output of crystalline photovoltaic cell modules), JIS C 8935 (Measuring methods of output of amorphous photovoltaic cell modules), and JIS C 8991 (Thin film photovoltaic (PV) modules installed on the ground—Requirements for certification of appropriate design and type certification).

A rated power generation of photovoltaic cells defined in the standards mentioned above is measured with the maximum power under the standard testing conditions (STC), which includes: solar radiation intensity of 1 kW/m², cell temperature of 25° C., and standard spectroscopic solar radiation of AM 1.5. Performance tests of photovoltaic cells are generally carried out with a solar simulator using a xenon lamp with a similar characteristic as the standard solar radiation of AM 1.5.

However, actually-needed photovoltaic cells are not those that deliver high output under the standard test conditions, but those that deliver high output under the condition of solar radiation at the actual place where the photovoltaic cells are installed.

Japanese Unexamined Patent Application Publication No. 2009-004704 discloses a stacked photovoltaic conversion device that has a first photoelectric conversion layer, a second photoelectric conversion layer, and a third photoelectric conversion layer stacked in this order from a light incident side, each layer having a pin junction and made of a silicon-based semiconductor. The photoelectric conversion device is characterized in that the short-circuit photocurrent of the first photoelectric conversion layer is larger than that of either one of the second photoelectric conversion layer and the third photoelectric conversion layer. The apparatus in this patent application avoids an extreme decrease in output power in the morning and evening, in which the amount of short wavelength light decreases, by making the short-circuit photocurrent of the first photoelectric conversion layer disposed at the incident light side greater than the photocurrent of the second and third photoelectric conversion layers.

Japanese Unexamined Patent Application Publication No. 2006-120747 discloses a thin film silicon formed photovoltaic cell that is so designed and manufactured that the generated current in a bottom photovoltaic cell layer is smaller than that in a top photovoltaic cell layer (at the light-incident side).

The solar light changes the weighted mean wavelength thereof corresponding to air mass, meteorological conditions such as the weather and the climate, and sunshine conditions such as the intensity of sunshine and the latitude of the place. Consequently, photovoltaic cells must be designed taking these conditions at the installation place into consideration to manufacture a photovoltaic cell that delivers high output power at the place of installation.

### SUMMARY OF THE INVENTION

The present invention provides a method and apparatus for manufacturing a thin film photovoltaic cell that delivers high output power at the place of installation.

A method for manufacturing a thin film photovoltaic cell according to the present invention manufactures a thin film photovoltaic cell that has a first electrode layer, a photoelectric conversion layer including a plurality of photoelectric conversion cells, and a second electrode layer sequentially formed on a substrate.

The method determines a structure of the photoelectric conversion cells including the photoelectric conversion layer, so as to confine the difference between a weighted mean wavelength of spectral sensitivity of the photoelectric conversion layer and a weighted mean wavelength of a spectrum of incident sunlight at a place of installing the thin film photovoltaic cell in a wavelength range that contributes to the power generation by the photovoltaic cell to a predetermined range.

Preferably in the method for manufacturing a thin film photovoltaic cell according to the present invention, the method determines a structure of the photoelectric conversion cells composing the photoelectric conversion layer so as to confine the difference between the weighted mean wavelength of spectral sensitivity of the photoelectric conversion layer and the weighted mean wavelength of the spectrum of incident sunlight at the place of installing the thin film photovoltaic cell in a wavelength range that contributes to power generation by the photovoltaic cell to a range of ±10%.

Preferably in the method for manufacturing a thin film photovoltaic cell according to the present invention, the weighted mean wavelength of the spectrum of incident sunlight at the place of installing the thin film photovoltaic cell is determined based on conditions of air mass, climate, and sunshine at the place of installing the thin film photovoltaic cell.

An apparatus for manufacturing a thin film photovoltaic cell according to the present invention manufactures a thin film photovoltaic cell having a first electrode layer, a photoelectric conversion layer composed of a plurality of photoelectric conversion cells, and a second electrode layer sequentially formed on a substrate. The apparatus comprises: an input device, a first database accumulating the relationship between a weighted mean wavelength of a sunlight spectrum incident to a ground surface and conditions of air mass, climate, and sunshine; a second database accumulating a relationship between a structure of the photoelectric conversion cells composing the photoelectric conversion layer and spectral sensitivity of the photoelectric conversion layer; a first operation device looking up the first database and obtaining a weighted mean wavelength of a spectrum of incident sunlight at a place of installing the thin film photovoltaic cell; a second operation device looking up the second database and obtaining structures of the photoelectric conversion cells so as to confine difference between a weighted mean wavelength of spectral sensitivity of the photoelectric conversion layer and a weighted mean wavelength of a spectrum of sunlight obtained by the first operation device in a wavelength range that contributes to power generation by the photovoltaic cell to a predetermined range; and a film depositing device receiving a signal from the second operation device and depositing films of the photoelectric conversion cells with the structures obtained by the second operation device.

In the method and apparatus of the invention, the structure of each of the photoelectric conversion cells constructing a photoelectric conversion layer is so determined that the difference between the weighted mean wavelength of spectral sensitivity in the photoelectric conversion layer and the weighted mean wavelength of the spectrum of incident sunlight at the installation place of the photovoltaic cell in the range of wavelength that contributes to power generation by the photovoltaic cell is confined to a predetermined range. Therefore, a thin film photovoltaic cell that delivers high output power at the installation place is manufactured.

### BRIEF DESCRIPTION OF DRAWINGS

FIG. 1 is a schematic drawing of a thin film photovoltaic cell manufactured according to an embodiment of the present invention;

FIG. 2 shows a relationship between the weighted mean wavelength of spectral sensitivity of the photoelectric conversion layer and the thicknesses of the top photoelectric conversion cell and the bottom photoelectric conversion cell;

FIG. 3 shows a relationship between the air mass and the weighted mean wavelength of the sun light spectrum reached the ground surface; and

FIG. 4 is a schematic block diagram of an apparatus for manufacturing a thin film photovoltaic cell according to an embodiment of the present invention.

### DETAILED DESCRIPTION OF THE INVENTION

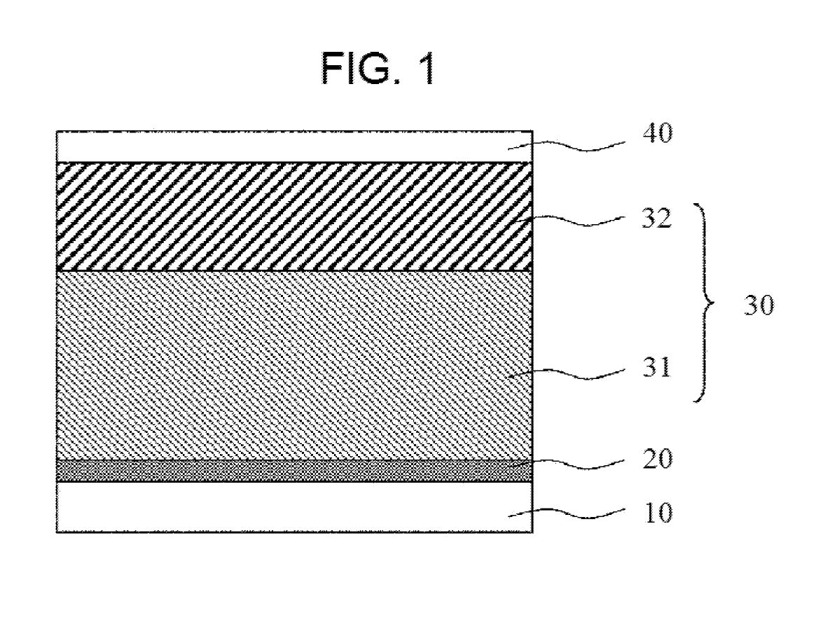

Now, a method of manufacturing a thin film photovoltaic cell according to an embodiment of the present invention will be described with reference to the thin film photovoltaic cell shown in FIG. 1.

The thin film photovoltaic cell of FIG. 1 is composed of a first electrode 20, a photoelectric conversion layer 30, and a second electrode layer 40 formed on a substrate 10.

The substrate 10 is not limited to special materials. Materials exhibiting good heat-resistant property are used preferably. Preferable materials include a glass substrate, a metal substrate with insulation treatment on the surface, and flexible films. Preferably used flexible materials include polyimide, polyethylene naphthalate, polyether sulfone, polyethylene terephthalate, and aramid. Using a substrate of flexible film provides a flexible thin film photovoltaic cell. A substrate disposed in the light incident side as in a super straight type photovoltaic cell must be, needless to say, composed of a transparent material.

Of the first electrode layer 20 and the second electrode layer 40, the electrode layer disposed at the light incident side, the second electrode layer 40 in this example, is formed of a transparent, electrically conductive oxide such as ITO, SnO₂, and ZnO. The electrode disposed opposite to the light incident side, the first electrode 20 in this example, is formed of an electrically conductive metal such as Ag, Ag alloy, Ni, Ni alloy, Al, and Al alloy. The layer of electrically conductive metal (hereinafter referred to as a “conductive metal layer”) can be covered with a layer of transparent, electrically conductive oxide such as ITO, SnO₂, and ZnO (hereinafter referred to as a “transparent conductive oxide layer”) formed on the conductive metal layer.

The method of forming the first electrode layer 20 and the second electrode layer 40 is not limited to a particular method. The electrode layers can be formed by depositing an electrode material by means of any film deposition method known in the art, for example, evaporation, sputtering and plating.

The photoelectric conversion layer 30 is composed of a plurality of photoelectric conversion cells with different band gaps. The photoelectric conversion layer 30 of this example is composed of a bottom photoelectric conversion cell 31 disposed at the side of the first electrode 20 and a top photoelectric conversion cell 32 disposed at the side of the second electrode 40. The photoelectric conversion cells are so arranged that the band gap is the widest in the cell at the light incident side and gradually decreases toward the cells away from the light incident side. Thus, the top photoelectric conversion cell 32 absorbs light in the short wavelength band and the bottom photoelectric conversion cell 31 absorbs light in the long wavelength band that has passed through the top photoelectric conversion cell 32. Therefore, the overall power generation efficiency is improved.

The photoelectric conversion cell in the invention is not limited to any special cell, but can be any cell such as a micro-crystalline silicon-based cell (hereinafter referred to as a “μc-Si cell”), an amorphous silicon-based cell (an “a-Si cell”), an amorphous silicon-germanium-based cell (an “a-SiGe cell”) or a compound-based photovoltaic cell. The μc-Si cell in the present invention means a photoelectric conversion cell that contains a micro-crystalline silicon film at least in the i-layer of the three layers of an n-layer, an i-layer, and a p-layer. The a-Si cell in the present invention means a photoelectric conversion cell in which three layers of an p-layer, an i-layer, and a p-layer are mainly composed of amorphous silicon-based films. The a-SiGe cell in the present invention means a photoelectric conversion cell in which an i-layer is formed of an amorphous silicon-germanium-based film. The compound-based photovoltaic cell in the present invention means a photoelectric conversion cell, typically the CIGS photovoltaic cell, formed of a thin film of a compound of Cu, In, Ga, and Se.

An example of the combination of a bottom photoelectric conversion cell 31 and a top photoelectric conversion cell 32 is the combination of the bottom photoelectric conversion cell 31 of a μc-Si cell and the top photoelectric conversion cell 32 of an a-Si cell.

The structure of the photoelectric conversion cells in a photoelectric conversion layer in the present invention is formed by so depositing cell materials that the difference, calculated as between the weighted mean wavelength of spectral sensitivity of the photoelectric conversion layer 30 and the weighted mean wavelength of the spectrum of incident sunlight that is at the place of installing the thin film photovoltaic cell and is in the wavelength range that contributes to power generation by the photovoltaic cell, is within a certain range. The structure of a photoelectric conversion cell in the present invention includes a film thickness, a composition, and crystallinity of the photoelectric conversion cell.

The spectral sensitivity of a photoelectric conversion layer depends on a thickness, a composition, and crystallinity of photoelectric conversion cells. The following describes an example of a relationship between the spectral sensitivity of a photoelectric conversion layer and the thicknesses of photoelectric conversion cells.

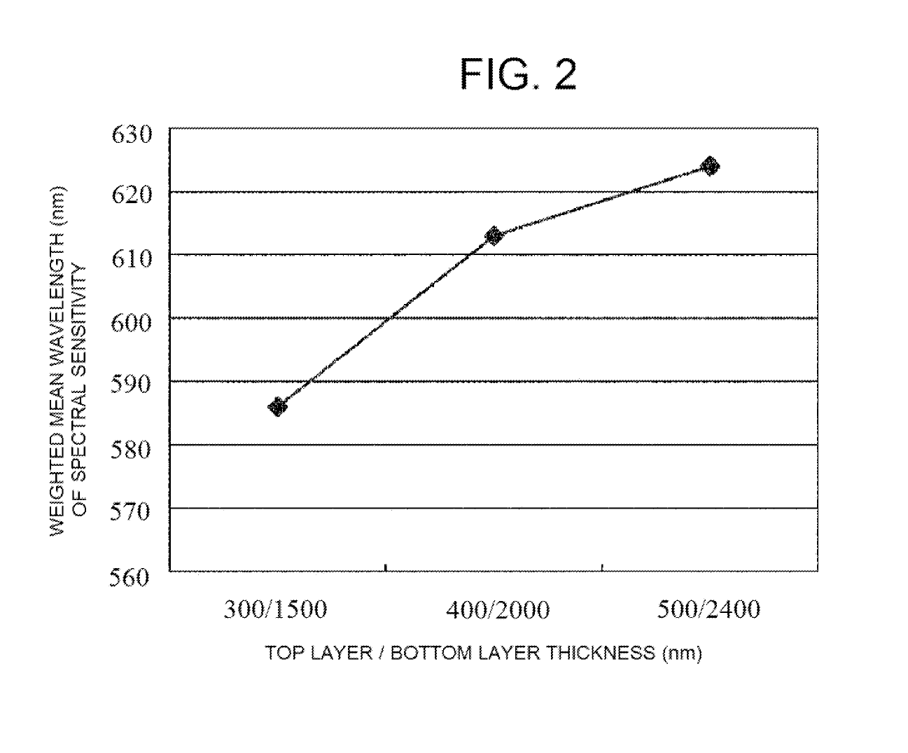

FIG. 2 shows a relationship between the weighted mean wavelength of spectral sensitivity of the photoelectric conversion layer 30 and the thicknesses of the top photoelectric conversion cell 32 and the bottom photoelectric conversion cell 31 of a multiple-junction type thin film photovoltaic cell including a top photoelectric conversion cell 32 of an a-Si cell and a bottom photoelectric conversion cell 31 of a μc-Si cell. FIG. 2 shows that decreasing the film thicknesses of the top photoelectric conversion cell 32 and the bottom photoelectric conversion cell 31 reduces the weighted mean wavelength of spectral sensitivity of the photoelectric conversion layer 30, and that increasing the film thicknesses of the top photoelectric conversion cell 32 and the bottom photoelectric conversion cell 31 increases the weighted mean wavelength of spectral sensitivity of the photoelectric conversion layer 30. Thus, the weighted mean wavelength of spectral sensitivity of the photoelectric conversion layer 30 can be controlled by adjusting the thicknesses and the ratio of thicknesses of the top photoelectric conversion cell 32 and the bottom photoelectric conversion cell 31.

An overall thickness of the photoelectric conversion layer is determined according to the optical absorption coefficient of the materials used and needs to be at least the film thickness of the optical absorption layer required by enough absorption. Alternatively, a necessary optical path length must be obtained by forming a light confinement structure at the first electrode layer or the second electrode layer. The thickness of the photoelectric conversion layer is adjusted primarily by varying the thickness of the i-layer. In that case, the p-layer and the n-layer are optimized corresponding to the change in the i-layer thickness.

Preferably, the difference in the weighted mean wavelength is at most ±10% between that of the spectral sensitivity of the photoelectric conversion layer 30 and that of the spectrum of the incident sunlight at the place installing the thin film photovoltaic cell in the range of wavelength for power generation by the photovoltaic cell. A small difference in the weighted mean wavelengths optimizes the power generation efficiency at the place of installing the thin film photovoltaic cell. In the specification and claims of the present invention, a “weighted mean wavelength of spectral sensitivity of the photoelectric conversion layer” means the wavelength at which the integral of spectral sensitivity of the photoelectric conversion layer 30 over the whole wavelength is divided into two equal half portions of the integral. Likewise, a “weighted mean wavelength of spectrum of incident sunlight at the place of installing the thin film photovoltaic cell” means the wavelength at which the integral of the spectrum of incident sunlight at the place of installing the thin film photovoltaic cell over the whole wavelength is divided into two equal half portions of the integral.

Preferably in the present invention, the structures of the photoelectric conversion cells composing the photoelectric conversion layer 30 are so designed that the difference between the maximum and the minimum of the generated current in the photoelectric conversion cells is in a predetermined range. Specifically this difference is, in the case of this embodiment example, the difference between the generated current of the bottom photoelectric conversion cell 31 and the generated current of the top photoelectric conversion cell 32. More preferably, this difference is at most 10% of the maximum value between the maximum value and the minimum value of the generated current in the photoelectric conversion cells composing the photoelectric conversion layer 30, and most preferably, this difference is not larger than 5%. Since the current generated in a multiple junction photovoltaic cell is determined by the current in the photoelectric conversion cell that generates smaller current, smaller difference in current between photoelectric conversion cells reduces a current transfer loss, thereby improving power generation efficiency of the thin film photovoltaic cell. The electric current generated in an individual photoelectric conversion cell can be measured by a wavelength-division of the light source of a solar simulator using an optical filter.

Since electric current generated in a photoelectric conversion cell, which depends on the structure of the photoelectric conversion cell, can be adjusted by the structure of the photoelectric conversion cell (for example, since the electric current generated in a photoelectric conversion cell increases with the increase in the film thickness of the photoelectric conversion cell), the difference in the generated electric current between photoelectric conversion cells can be reduced by adjusting the thickness of the photoelectric conversion cells.

The weighted mean wavelength of the spectrum of incident sun light at the place of installing a thin film photovoltaic cell in the wavelength range contributing power generation of the photovoltaic cell in the present invention is preferably determined based on the conditions at the place of installing the thin film photovoltaic cell including: the air mass, meteorological conditions such as region and weather, and sunshine conditions such as a rate of fine weather days, a geographical condition, and yellow sand and other regional conditions, and seasonal variation thereof.

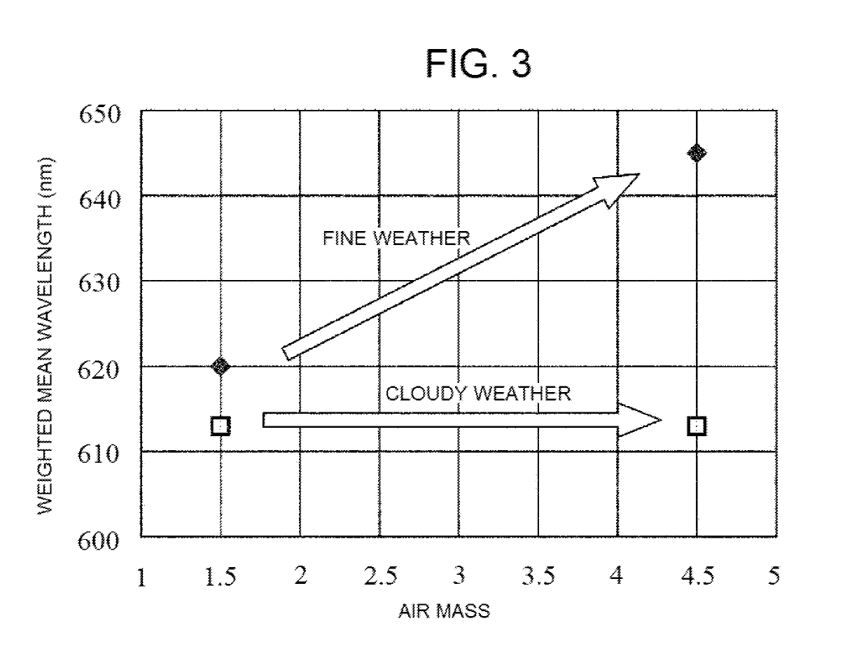

Table 1 shows factors affecting the weighted mean wavelength of the sunlight spectrum; and FIG. 3 illustrates the relationship between an air mass, which indicates transparency of solar radiation through mass of air, and the weighted mean wavelength of the spectrum of the sunlight reached the ground surface.

| | weighted mean wavelength of the spectrum of | | |
|---|---|---|---|
| | sunlight reached the ground surface | | |
| | shift to longer | shift to shorter | |
| | wavelength (red | wavelength (blue | factors for |
| item | color) region | color) region | variaiton |
| air mass | large: high latitude | small: low latitude | season |
| | area, morning and | area, day time, | |
| | evening, winter | summer | |
| moisture | small: fine days, | large: rainy and | season, |
| | winter, cold region, | cloudy days, summer, | weather |
| | little rain and dry | hot region, wet | |
| | weather | weather | |
| aerosol | large: yellow | small | region, |
| | sand | | season |

As shown in FIG. 3, the weighted mean wavelength shifts to the longer wavelength region (red-colored light region) with an increase in air mass in fine days. In cloudy days, however, the weighted mean wavelength is hardly affected by the air mass and remains substantially constant.

Thus, the weighted mean wavelength of the sunlight spectrum is affected by a ground configuration and climate conditions as well as the geographical position such as latitude. Therefore, the power generation efficiency of a thin film photovoltaic cell can be optimized for the place of installation by obtaining the weighted mean wavelength of the incident sunlight spectrum at the place of installing the thin film photovoltaic cell based on the conditions of the air mass, climate, and sunshine.

The weighted mean wavelength of the incident sunlight spectrum at the place of installing the thin film photovoltaic cell can be obtained by measuring the sunlight spectrum periodically in the morning and evening on fixed days in fixed months after selecting typical spots based on climate and geographical data issued by meteorological observatories.

If the measurement of sunshine data is difficult, reference is possible to BSRN (Baseline Surface Radiation Network) and WRDC (World Radiation Data Centre).

An example of the design of a structure of a photoelectric conversion cell is described in the following. In a region where the weighted mean wavelength of the sunlight spectrum is in a range of the short wavelength (region of blue color transition), the thickness of the top photoelectric conversion cell 32 is increased and the light absorption in the top photoelectric conversion cell 32 is enhanced to increase the weighted mean wavelength of spectral sensitivity of the photoelectric conversion layer 30. The film thickness of the bottom photoelectric conversion cell 31 is so adjusted as to reduce the difference between the generated current in the top photoelectric conversion cell 32 and the generated current in the bottom photoelectric conversion cell 31. In a region where the weighted mean wavelength of the sunlight spectrum is in a range of long wavelength (region of red color transition), the thickness of the top photoelectric conversion cell 32 is decreased and the light transparency in the top photoelectric conversion cell 32 is enhanced to decrease the weighted mean wavelength of spectral sensitivity of the photoelectric conversion layer 30. Thus, the film thickness of the bottom photoelectric conversion cell 31 is so adjusted as to reduce the difference between the generated current in the top photoelectric conversion cell 32 and the generated current in the bottom photoelectric conversion cell 31. Such design improves power generation efficiency of a thin film photovoltaic cell.

It is also possible to manufacture general purpose products of thin film photovoltaic cells corresponding to conditions of air mass, climate, and sunshine as shown in Table 2 for selling to general customers, not special clients, or in cases when starting from assessment is inconvenient because of the production procedure or the deadline for delivery. It is further possible to design general purpose products using feedback information obtained in the design and manufacture process based on the assessment described above.

TABLE 2

| | | | weighted mean wavelength of spectral |
|---|---|---|---|
| | air | | sensitivity of a photoelectric |
| place | mass | climate | conversion layer |
| high | Large | little | longer wavelength |
| latitude | | rain, dry | ↓ |
| | | wet | ↓ |
| low | small | little | shorter wave length |
| latitude | | rain, dry | |
| | | wet | |

Now, the following describes an apparatus for manufacturing a thin film photovoltaic cell according to an embodiment of the present invention.

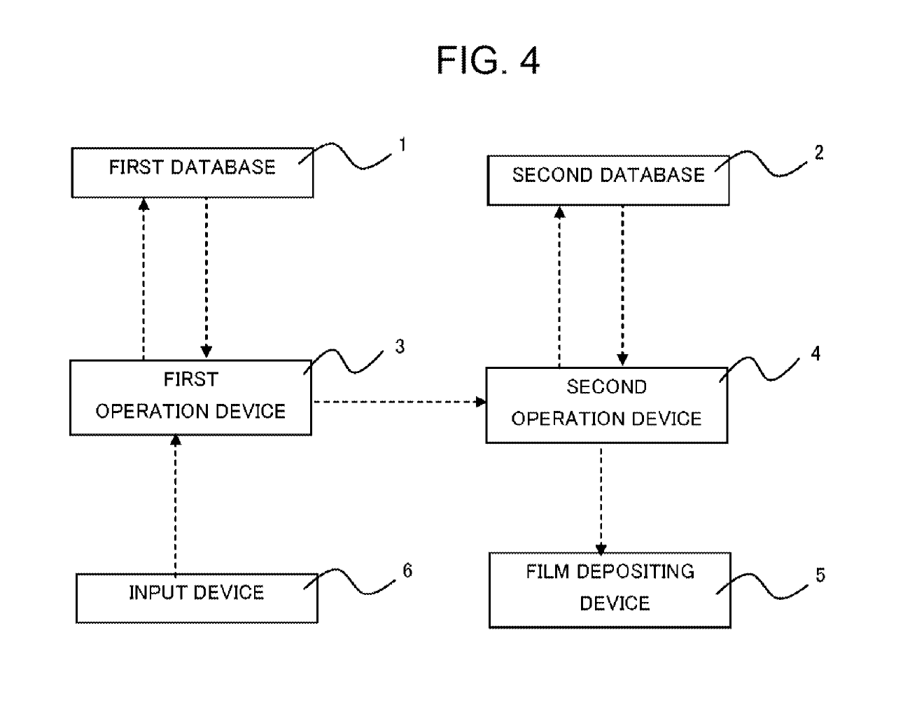

As shown in FIG. 4, an apparatus for manufacturing a thin film photovoltaic cell comprises: an input device 6, a first database 1 accumulating the relationship between the weighted mean wavelength of the sunlight spectrum incident to the ground surface and conditions of air mass, climate, and sun shine; a second database 2 accumulating the relationship between the structure of photoelectric conversion cells composing the photoelectric conversion layer 30 and the generated current in the photoelectric conversion cells, and the relationship between the structure of photoelectric conversion cells and the spectral sensitivity of the photoelectric conversion layer 30; a first operation device 3 obtaining a weighted mean wavelength of the spectrum of the incident sunlight at the place of installing the thin film photovoltaic cell; a second operation device 4 obtaining the structure of the photoelectric conversion cells composing the photoelectric conversion layer 30; and a film depositing device 5.

The input device 6 sends input data to the first operation device 3. The input data may include, for example, air mass at an installation location, weather conditions (e.g. weather, climate, location), and sunshine conditions (e.g. solar radiation intensity, latitude, rate of clear weather, regionally specific condition such as yellow sand from the Yellow River region in china, and seasonal variation of these conditions).

The first database 1 stores information related to the relationship between the weighted mean wavelength of the sunlight spectrum incident to the ground surface and conditions of air mass, climate, and sun shine. More specifically, the data set stored on the first database 1 includes such conditions as air mass at an installation location, weather conditions (e.g. weather, climate, location), and sunshine conditions (e.g. solar radiation intensity, latitude, rate of clear weather, regionally specific condition such as yellow sand from the Yellow River region in china, and seasonal variation of these conditions), as well as the weighted mean wavelength of a spectrum of the incident sunlight that is at the place of installation of the thin film photovoltaic cell and is in a wavelength range contributing to power generation by the thin film photovoltaic cell under these conditions.

The second database 2 stores information related to the relationship between the structure of photoelectric conversion cells composing the photoelectric conversion layer 30 and the generated current in the photoelectric conversion cells, and the relationship between the structure of photoelectric conversion cells and the spectral sensitivity of the photoelectric conversion layer 30. More specifically, the data set stored on the second database 2 includes the forming conditions of various photoelectric conversion layer 30 (e.g. film thickness of each layer, dopant concentration for n-layer and p-layer of each cell), and the weighted mean wavelength in spectral sensitivity of photoelectric conversion layer 30 formed under these respective conditions. This data set is accumulated using preliminarily acquired experimental results, and new data based on experimental results may be added to correct data in the existing data set.

The data set of the second database 2 has the following features: (1) the larger is the thickness of a top photoelectric conversion cell 32, the smaller is the value of the weighted mean wavelength in spectral sensitivity of photoelectric conversion layer 30, and (2) the larger is the thickness of a bottom photoelectric conversion cell 31, the larger is the value of the weighted mean wavelength in spectral sensitivity of photoelectric conversion layer 30. Further, if a single top photoelectric conversion cell 32 or a single bottom photoelectric conversion cell 32 is used as the photoelectric conversion layer 30, the shift of the weighted mean wavelength does not occur. The weighted mean wavelength in a single cell is substantially determined by the material of the cell. Thus, the weighted mean wavelength in spectral sensitivity of photoelectric conversion layer 30 composed of a plurality of cells varies with the balance in thickness of each cell.

The first operation device 3 looks up the sunlight spectrum, at the place concerned, stored in the first database and integrates the spectral radiation intensity of the sunlight spectrum over absorption wavelength region of the thin film photovoltaic cell to be supplied, and calculates a weighted mean wavelength of the spectrum of the incident sunlight at the place of installing the thin film photovoltaic cell, the weighted mean wavelength being the wavelength at which the integral of the spectral radiation intensity over whole the wavelength region is divided into two equal halves of the integral. The result of the operation is delivered to the second operation device 4.

More specifically, the first operation device 3 receives input data from the input device 6. The input data include, for example, air mass at an installation location, weather conditions (e.g. weather, climate, location), and sunshine conditions (e.g. solar radiation intensity, latitude, rate of clear weather, regionally specific condition such as yellow sand from the Yellow River region in china, and seasonal variation of these conditions). The first operation device 3 refers to the first database 1 on the basis of the aforementioned input data, and selects the closest data set with regard to “air mass at an installation location”, “weather conditions (weather, climate, location)” and “sunshine conditions (solar radiation intensity, latitude, rate of clear weather, regionally specific condition such as yellow sand from the Yellow River region in china, and seasonal variation of these conditions).” Subsequently, the first operation device 3 outputs to the second operation device 4 “the weighted mean wavelength in the range of wavelength involved in the power generation using solar spectrum incident to the surface of the ground” of this data set.

The second operation device 4 looks up the second database and conducts operation to find out such a structure of photoelectric conversion cells that makes the difference between the weighted mean wavelength of spectral sensitivity of the photoelectric conversion layer 30 and the weighted mean wavelength of the sunlight spectrum determined in the first operation device 3 within a predetermined range. Preferably, the structure of photoelectric conversion cells is so determined that the difference between the maximum and the minimum of the generated current in the photoelectric conversion cells composing the photoelectric conversion layer 30 is within a predetermined range. The results of the operation are delivered to the film depositing device 5.

More specifically, the second operation device 4 receives the data of “the weighted mean wavelength in the range of wavelength involved in the power generation using solar spectrum” outputted from the first operation device 3. The second operation device refers to the second database on the basis of the aforementioned data, and selects the data set in which the value of the weighted mean wavelength is closest to “the weighted mean wavelength in the range of wavelength involved in the power generation using solar spectrum from among “the weighted mean wavelength in spectral sensitivity of photoelectric conversion layer 30 made by respective conditions.” In the selection of data set, it is desired that the difference between “the weighted mean wavelength in spectral sensitivity of photoelectric conversion layer 30” and “the weighted mean wavelength in the range of wavelength involved in the power generation using solar spectrum” which was acquired by the first operation device 3 is within ±10%. Then, the second operation device outputs to the film depositing device 5 “forming conditions of photoelectric conversion layer 30 (film thickness of each layer, dopant concentration for n-layer and p-layer of each cell)” of this data set.

The film depositing device 5 can be a known film depositing device, for example, a plasma CVD device. The film depositing device 5 sets film deposition conditions based on the output of the second operation device 4 so as to achieve the structure obtained by the second operation device 4, and carries out film deposition to form a photoelectric conversion layer 30.

What is claimed is:

1. A method for manufacturing a thin film photovoltaic cell having a first electrode layer, a photoelectric conversion layer including a plurality of photoelectric conversion cells, and a second electrode layer sequentially formed on a substrate, the method comprising:
calculating a difference between a weighted mean wavelength of spectral sensitivity of the photoelectric conversion layer and a weighted mean wavelength of a spectrum of incident sunlight that is at a place of installation of the thin film photovoltaic cell and is in a wavelength range contributing to power generation by the thin film photovoltaic cell; and
determining a structure of the photoelectric conversion cells, such that the difference is confined to a predetermined range.

2. The method of claim 1, wherein the predetermined range is ±10%.

3. The method of claim 2, wherein the calculating includes determining the weighted mean wavelength of the spectrum of incident sunlight based on conditions of air mass, climate, and sunshine at the place of installation.

4. The method of claim 1, wherein the calculating includes determining the weighted mean wavelength of the spectrum of incident sunlight based on conditions of air mass, climate, and sunshine at the place of installation.

5. The method of claim 1, wherein the weighted mean wavelength of spectral sensitivity is a wavelength at which an integral of the spectral sensitivity over an entire spectrum thereof is divided into two equal halves.

6. The method of claim 1, wherein the weighted mean wavelength of the spectrum of incident sunlight is a wavelength at which an integral of the spectrum of incident sunlight is divided into two equal halves.

7. A method for manufacturing a thin film photovoltaic cell having a first electrode layer, a photoelectric conversion layer including a plurality of photoelectric conversion cells, and a second electrode layer, the method comprising:
calculating a difference between a weighted mean wavelength of spectral sensitivity of the photoelectric conversion layer and a weighted mean wavelength of a spectrum of incident sunlight that is at a place of installation of the thin film photovoltaic cell and is in a wavelength range contributing to power generation by the thin film photovoltaic cell;
determining a structure of the plurality of photoelectric conversion cells, such that the calculated difference is confined to a predetermined range; and
forming the first electrode layer, the plurality of photoelectric conversion cells, and the second electrode layer sequentially on a substrate, the plurality of photoelectric conversion cells being formed in accordance with the determined structure.

8. The method of claim 7, wherein the calculating includes determining the weighted mean wavelength of the spectrum of incident sunlight based on conditions of air mass, climate, and sunshine at the place of installation.

9. The method of claim 7, wherein the weighted mean wavelength of spectral sensitivity is a wavelength at which an integral of the spectral sensitivity over an entire spectrum thereof is divided into two equal halves.

10. The method of claim 7, wherein the weighted mean wavelength of the spectrum of incident sunlight is a wavelength at which an integral of the spectrum of incident sunlight is divided into two equal halves.

11. An apparatus for manufacturing a thin film photovoltaic cell having a first electrode layer, a photoelectric conversion layer including a plurality of photoelectric conversion cells, and a second electrode layer sequentially formed on a substrate, the apparatus comprising:
a first database accumulating a relationship between a weighted mean wavelength of a sunlight spectrum incident to a ground surface and conditions of air mass, climate, and sunshine;
a second database accumulating a relationship between a structure of the photoelectric conversion cells and spectral sensitivity of the photoelectric conversion layer;
a first operation device looking up the first database and obtaining a weighted mean wavelength of a spectrum of incident sunlight at a place of installation of the thin film photovoltaic cell;
a second operation device looking up the second database and obtaining the structure of the photoelectric conversion cells, such that a difference between a weighted mean wavelength of spectral sensitivity of the photoelectric conversion layer and the weighted mean wavelength of a spectrum of sunlight obtained by the first operation device in a wavelength range that contributes to power generation by the photovoltaic cell is confined to a predetermined range; and
a film depositing device receiving a signal from the second operation device and depositing films of the photoelectric conversion cells with the structure obtained by the second operation device.

12. The apparatus of claim 11, wherein the weighted mean wavelength of spectral sensitivity is a wavelength at which an integral of the spectral sensitivity over an entire spectrum thereof is divided into two equal halves.

13. The apparatus of claim 11, wherein the weighted mean wavelength of the spectrum of incident sunlight is a wavelength at which an integral of the spectrum of incident sunlight is divided into two equal halves.
